(19) United States
(12) Patent Application Publication
(10) Pub. No.: US 2009/0050352 A1
(43) Pub. Date: Feb. 26, 2009

(54) SUBSTRATE STRUCTURES FOR FLEXIBLE ELECTRONIC DEVICES AND FABRICATION METHODS THEREOF

(75) Inventors: Liang-Hsiang Chen, Taichung (TW); Jia Chong Ho, Taipei Hsien (TW); Jing-Yi Yan, Taoyuan County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: INDUSTRIAL TECHNOLOGY RESEARCH INSTITUTE, Hsinchu (TW)

(21) Appl. No.: 12/112,020

(22) Filed: Apr. 30, 2008

(30) Foreign Application Priority Data
Aug. 20, 2007 (TW) 96130691

(51) Int. Cl. H05K 1/00; H01L 21/00

(52) U.S. Cl. 174/254; 438/123; 257/E21.001

(57) ABSTRACT

The invention provides flexible electronic substrate structures and fabrication methods thereof. The flexible electronic substrate structures include a large scale carrier and a plurality of flexible substrates disposed on the large scale carrier, wherein the flexible substrate includes polymeric material formed by coating. The flexible substrates are patterned polymer materials formed by a coating process, wherein the coating process comprises doctor knife coating, spin coating, or table coating.

### BACKGROUND OF THE INVENTION

1. Field of the Invention

The invention relates to flexible electronic devices, and more particularly to substrate structures for flexible electronic devices and fabrication methods thereof.

2. Description of the Related Art

Flexible electronic devices, such as flexible transistors, flexible memories, and printer antennas, are electronic devices configured with or arranged on soft or bendable substrates including thin plastic plates or thin metal plates. Flexible electronic devices usually use amorphous silicon, low-temperature silicon, or organic semiconductor materials and are integrated with other printing techniques and continuous optical electronic thin-film assembly processes.

Conventional fabrication methods for flexible electronic devices mainly include printing processes. Functional materials are printed on flexible plastic substrates to manufacture flexible electronic devices. Applications for flexible electronic devices include flexible electronic books, electronic newspapers, ultra-thin cell phones, wrist digital watches, and sensors.

Since, during fabrication of thin-film transistors on a flexible display, it is difficult to fix plastic substrates by a clamp, in efforts to adhere the plastic substrate to a glass substrate, resins are utilized. Therefore, facilitating multiple lithography and etching processes for fabricating thin-film transistors. After the multiple lithography and etching processes are completed, the plastic substrates are detached and then assemble with other elements. The detachment procedures, however, always leaves resin residue on the plastic substrates. The resin residue is very difficult to remove. Moreover, since the coefficient of thermal expansions (CTE) of the resin and the plastic substrate respectively are different, misalignment becomes a severe problem. In order to solve the misalignment problem, polymer solution materials are applied to a carrier substrate. The polymer solution is then dried and turned into a plastic substrate. The CTE of the carrier substrate is smaller than the CTE of the plastic substrate such that misalignment problems do not occur. The polymer material must be strong enough to sustain all of the fabrication processes and then be detached from the carrier substrate. Typical polymer materials include polyimide (PI), polyethylenenaphthalate (PEN), polyethersulfone (PES), and the likes with a thickness in a range between about 5-200 μm.

Taiwan Pat. Application No. 94131431 and WO 2005/050754 A1, the entireties of which are hereby incorporated by reference, disclose methods for applying polymer paint on a carrier substrate. Since the polymer flexible substrate consistently shrinks or expands in both x-axis and y-axis directions with the carrier substrate during multiple lithography and etching processes, the polymer flexible substrate can be cut into desirable dimensions. The entirely coated polymer flexible substrate is wrapped after cutting procedures due to stress release at fringe of the flexible substrate, such that the subsequent flexible circuit board cannot be attached on the flexible substrate successfully.

### BRIEF SUMMARY OF THE INVENTION

A detailed description is given in the following embodiments with reference to the accompanying drawings.

Embodiments of the invention provide a substrate structure for flexible electronic devices, comprising a large scale carrier, and a plurality of flexible substrates disposed on the large scale carrier.

Embodiments of the invention further provide a fabrication method for a flexible electronic device, comprising providing a large scale carrier, and locally applying flexible substrates in a checkerboard pattern on the large scale carrier.

It should be noted that the fabrication method for a flexible electronic device further comprises forming at least one thin-film transistor (TFT) on each flexible substrate, cutting the large scale carrier along an interval between each flexible substrate to divide a plurality of carrier structures with a flexible substrate thereon, and attaching a flexible printed circuit (FPC) board on the flexible substrate after cutting each carrier structure with a flexible substrate thereon.

### BRIEF DESCRIPTION OF THE DRAWINGS

The invention can be more fully understood by reading the subsequent detailed description and examples with references made to the accompanying drawings, wherein:

FIG. 1 is a schematic view of an embodiment of a substrate structure for flexible electronic devices of the invention; and

FIGS. 2A-2C are schematic views of each fabrication method step for flexible electronic devices of the invention.

### DETAILED DESCRIPTION OF THE INVENTION

It is to be understood that the following disclosure provides many different embodiments, or examples, for implementing different features of various embodiments. Specific examples of components and arrangements are described below to simplify the present disclosure. These are merely examples and are not intended to be limiting. In addition, the present disclosure may repeat reference numerals and/or letters in the various examples. This repetition is for the purpose of simplicity and clarity and does not in itself indicate a relationship between the various embodiments and/or configurations discussed. Moreover, the formation of a first feature over or on a second feature in the description that follows may include embodiments in which the first and second features are formed in direct contact or not in direct contact.

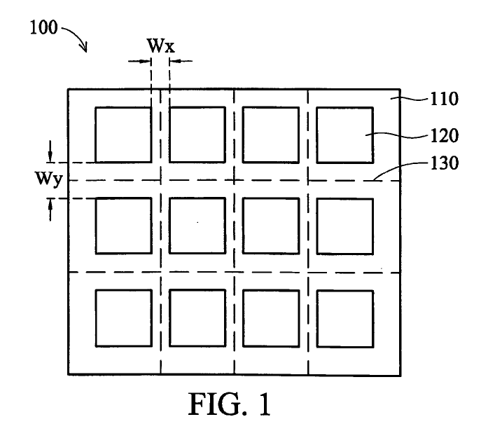

FIG. 1 is a schematic view of an embodiment of a substrate structure for flexible electronic devices of the invention. In FIG. 1, a substrate structure 100 for flexible electronic devices includes a large scale carrier 110 and a plurality of flexible substrates 120 disposed on the large scale carrier 110. A polymer paint solution is applied on the large scale carrier by a coater such as a slot-die coater. Flexible substrate regions 120 are locally applied in a checkerboard pattern on the large scale carrier 110. After the patterned polymer paint solution regions are coated, curing processes are performed thereon for polymerization. The curing processes include thermal curing and light curing processes.

According to embodiments of the invention, the large scale carrier can be a rigid substrate including glass, quartz, or a silicon wafer. Each flexible substrate along the x-axis direction is apart from each other with an interval Wx of about 3 cm to 5 cm, and each flexible substrate along the y-axis direction is apart from each other with an interval Wy of about 3 cm to 5 cm. Both the interval Wx and interval Wy are used as a kerf line (or cutting lane) 130 for substrate separation. Note that embodiments of the invention are disclosed by, but are not limited to, providing intervals in a range of between 3 cm and 5 cm in practical applications. Since only the rigid carrier substrate is exposed on the kerf line (or cutting lane) 130, the flexible substrate will not be cut, and warping can thus be prevented. The subsequent bonding process of the flexible printed circuit (FPC) board can be achieved, thereby reducing production costs and improving process efficiency.

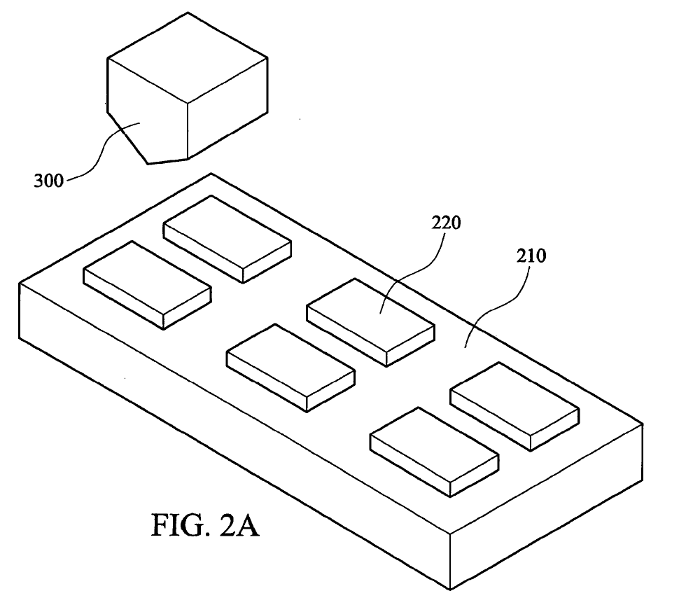

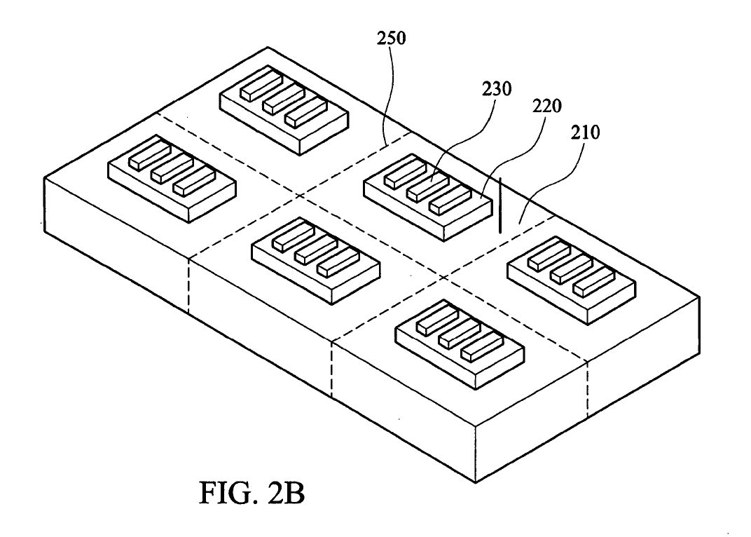

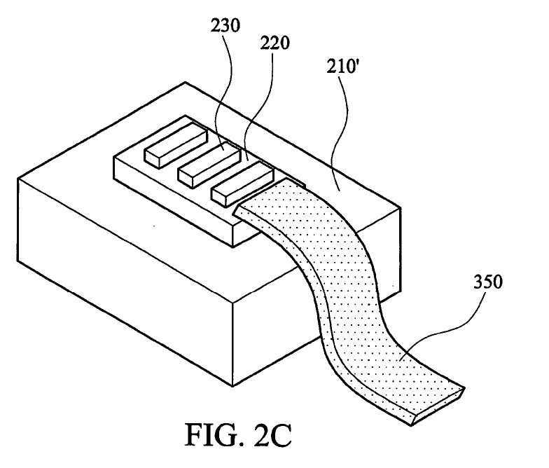

FIGS. 2A-2C are schematic views of each fabrication method step for flexible electronic devices of the invention. Referring to FIG. 2A, polymer paint solution is applied on a large scale carrier 210 by using a slot-die head 300 of a slot-die coater. The coating method includes forming a plurality of flexible substrates 220 in checkerboard patterns, wherein the flexible substrate is made of polymer material by slot-die coating. Subsequently, a thermal curing or a light curing process is performed to polymerize the flexible substrate.

Referring to FIG. 2B, at least one electronic device 230 is formed on the flexible substrate 220. For example, at least one thin film transistor (TFT), such as an inorganic TFT, an organic TFT, or a hybrid TFT, is formed on each flexible substrate. The thin-film transistor (TFT) comprises a substrate, an electrode, an insulator layer and a semiconductor layer. The insulator layer comprises organic materials, inorganic materials, organic-inorganic hybrid materials, or composite materials. The semiconductor layer comprises an inorganic semiconductor layer, an organic oligomer layer, an organic polymer layer, and an organic-inorganic hybrid layer. Further, the electrode comprises an inorganic conductor, an organic oligomer or an organic polymer semiconductor doped with conductive metal ions.

Subsequently, the large scale carrier substrate 210 is cut along an interval (i.e., kerf line or cutting lane) 250 between each flexible substrate 220, to divide a plurality of carrier structures with a flexible substrate thereon.

Referring to FIG. 2C, after cutting each carrier structure with a flexible substrate thereon, a flexible printed circuit (FPC) board 350 is bounded on the flexible substrate, thereby electrically connecting the electronic devices on the flexible substrate to the outer control circuits. Subsequently, the flexible substrate is delaminated from the cut carrier substrate.

Embodiments of the invention are advantageous in that patterned flexible substrates are locally formed on a large scale rigid carrier substrate by a slot-die coater. The flexible substrates are apart from each other with an interval in a range between about 3 cm and 5 cm for kerf lines or cutting lanes. The warped flexible substrate problems can thus be eliminated and the subsequent flexible printed circuit (FPC) board bonding process can also be facilitated, thereby reducing production costs and improving process efficiency.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A substrate structure for flexible electronic devices, comprising:
a large scale carrier; and
a plurality of flexible substrates disposed on the large scale carrier.

2. The substrate structure for flexible electronic devices as claimed in claim 1, wherein the flexible substrates are patterned polymer materials formed by a coating process, wherein the coating process comprises doctor knife coating, spin coating, or table coating.

3. The substrate structure for flexible electronic devices as claimed in claim 1, wherein the flexible substrates comprises at least one thin-film transistor (TFT).

4. The substrate structure for flexible electronic devices as claimed in claim 3, wherein the thin-film transistor (TFT) comprises a substrate, an electrode, an insulator layer and a semiconductor layer.

5. The substrate structure for flexible electronic devices as claimed in claim 3, wherein the thin-film transistor (TFT) comprises an inorganic TFT, an organic TFT, or a hybrid TFT.

6. The substrate structure for flexible electronic devices as claimed in claim 4, wherein the insulator layer consists of a structure covering and blocking an upper conductive line.

7. The substrate structure for flexible electronic devices as claimed in claim 4, wherein the insulator layer comprises organic materials, inorganic materials, organic-inorganic hybrid materials, or composites.

8. The substrate structure for flexible electronic devices as claimed in claim 4, wherein the semiconductor layer comprises an inorganic semiconductor layer, an organic oligomer layer, an organic polymer layer, and an organic-inorganic hybrid layer.

9. The substrate structure for flexible electronic devices as claimed in claim 4, wherein the electrode comprises an inorganic conductor, an organic oligomer or an organic polymer semiconductor doped with conductive metal ions.

10. The substrate structure for flexible electronic devices as claimed in claim 1, wherein each flexible substrate is apart from each other with an interval about 3 cm to 5 cm.

11. The substrate structure for flexible electronic devices as claimed in claim 10, wherein the interval between each flexible substrate comprises a kerf line for cutting.

12. The flexible electronic substrate structure as claimed in claim 1, wherein the large scale carrier is a rigid substrate comprising glass, quartz, or a silicon wafer.

13. The substrate structure for flexible electronic devices as claimed in claim 1, wherein the flexible substrates are bendable substrates comprising plastic substrates.

14. A fabrication method for a flexible electronic device, comprising:
providing a large scale carrier; and
locally applying flexible substrates in a checkerboard pattern on the large scale carrier.

15. The fabrication method as claimed in claim 14, wherein the flexible substrate is applied by slot die coating.

16. The fabrication method as claimed in claim 14, further comprising forming at least one thin-film transistor (TFT) on each flexible substrate.

17. The fabrication method as claimed in claim 16, wherein the thin-film transistor (TFT) comprises a substrate, an electrode, an insulator layer and a semiconductor layer.

18. The fabrication method as claimed in claim 16, wherein the thin-film transistor (TFT) comprises an inorganic TFT, an organic TFT, or a hybrid TFT.

19. The fabrication method as claimed in claim 14, further comprising cutting the large scale carrier along an interval between each flexible substrate, to divide a plurality of carrier structures with a flexible substrate thereon.

20. The fabrication method as claimed in claim 19, wherein after cutting each carrier structure with a flexible substrate thereon, further comprising attaching a flexible printed circuit (FPC) board on the flexible substrate.
